(19) United States
(12) Patent Application Publication
(10) Pub. No.: US 2022/0004275 A1
(43) Pub. Date: Jan. 6, 2022

(54) TOUCH STRUCTURE AND DISPLAY PANEL

(71) Applicant: Wuhan China Star Optoelectronics Semiconductor Display Technology Co., Ltd., Wuhan (CN)

(72) Inventor: Weixin Ma, Wuhan (CN)

(21) Appl. No.: 16/641,306

(22) PCT Filed: Oct. 31, 2019
(86) PCT No.: PCT/CN2019/114542

§ 371 Date: Feb. 24, 2020

(30) Foreign Application Priority Data
Aug. 21, 2019 (CN) 201910774553.5

(51) Int. Cl. G06F 3/041; G06F 3/044

(52) U.S. Cl. CPC G06F 3/0412; G06F 2203/04111; G06F 2203/04107; G06F 3/0446

(57) ABSTRACT

The present invention provides a touch structure and a display panel. The touch structure includes touch electrodes and a light shielding layer. An electrode gap is arranged between each adjacent two of the touch electrodes. The light shielding layer is arranged at one side of the touch electrodes. The light shielding layer is arranged corresponding to the electrode gaps.

### 1. FIELD OF DISCLOSURE

The present invention relates to a field of display panels and in particular, to a touch structure and a display panel.

### 2. DESCRIPTION OF RELATED ART

With development of large-screen mobile phones, touch control technology has also been developed rapidly. The current touch control technologies basically have two types, one is a self-capacitive touch structure, and the other is a mutual-capacitive touch structure.

At present, the touch control technologies used in active-matrix organic light-emitting diode (AMOLED) displays are typically mutual-capacitive touch structures. As shown in FIG. 1, the mutual-capacitive touch structure includes first touch electrodes 11 arranged in a longitudinal direction and second touch electrodes 12 arranged in a lateral direction. In a manufacturing process, in order to prevent the first touch electrodes 11 and the second touch electrodes 12 from being short-circuited with each other, a distance between the first touch electrode 11 and the second touch electrode 12 is generally slightly larger. However. However, an overly large electrode gap between the first touch electrode 11 and the second touch electrode 12 causes uneven brightness (Mura) at the electrode gap between the first touch electrode 11 and the second touch electrode 12 of a display panel, thus lowering display quality.

### SUMMARY

The present invention provides a touch structure and a display panel to solve an uneven brightness problem resulting from an overly large electrode gap between the touch electrodes in a conventional touch structure.

The present invention provides a touch structure, comprising:

a plurality of touch electrodes, an electrode gap defined between each adjacent two of the touch electrodes; and

a light shielding layer disposed at one side of the touch electrodes, wherein the light shielding layer is disposed corresponding to the electrode gaps.

The light shielding layer is made of a black matrix photoresist material.

The touch structure further comprises a protective layer, the protective layer is disposed on the touch electrodes, and the light shielding layer is disposed on the protective layer.

The touch electrodes comprise a plurality of first touch electrodes and a plurality of second touch electrodes, and the first touch electrodes and the second touch electrodes are electrically insulated from each other and intersect with each other to form a mutual capacitive electrode structure.

The first touch electrodes are arranged in a plurality of columns along a first direction; each two adjacent ones of the first touch electrodes in each column are electrically connected to each other; the second touch electrodes are arranged in a plurality of rows along a second direction; each two adjacent ones of the second touch electrodes in each cow are electrically connected to each other; and the first direction is perpendicular to the second direction.

A metal line is disposed at each intersection of the first touch electrodes and the second touch electrodes; wherein each two adjacent ones of the first touch electrodes of each column are electrically connected through the metal line; and the protective layer is disposed on the metal line.

A plurality of bridges are disposed at one side of the touch electrodes away from the light shielding layer, wherein the bridges are disposed corresponding to the intersections of the first touch electrodes and the second touch electrodes, and each two adjacent ones of the second touch electrodes in each row are electrically connected through the bridge.

An insulating layer is disposed between the metal lines and the bridges, wherein a plurality of through holes are defined in the insulating layer, and each two adjacent ones of the second touch electrodes in each row are electrically connected to a corresponding one of the bridges through the through holes.

The touch structure further comprises a buffer layer, wherein the bridges are disposed on the buffer layer, and the insulating layer is disposed on the buffer layer.

The present invention further provides a display panel, comprising:

a substrate;

a light emitting layer disposed on the substrate; and

a touch structure disposed at one side of the light emitting layer away from the substrate, the touch structure comprising:
a plurality of touch electrodes, an electrode gap defined between each two adjacent ones of the touch electrodes; and
a light shielding layer disposed at one side of the touch electrodes away from the light emitting layer, wherein the light shielding layer is disposed corresponding to the electrode gaps.

The light shielding layer is made of a black matrix photoresist material.

The touch structure further comprises a protective layer, the protective layer is disposed on the touch electrodes, and the light shielding layer is disposed on the protective layer.

The touch electrodes comprise a plurality of first touch electrodes and a plurality of second touch electrodes, the first touch electrodes and the second touch electrodes are insulated from each other and intersect with each other to form a mutual capacitive electrode structure.

The first touch electrodes are arranged in a plurality of columns along a first direction; each two adjacent ones of the first touch electrodes in each column are electrically connected to each other; the second touch electrodes are arranged in a plurality of rows along a second direction; each two adjacent ones of the second touch electrodes in each cow are electrically connected to each other; and the first direction is perpendicular to the second direction.

The display panel further comprises a metal line disposed at each intersection of the first touch electrodes and the second touch electrodes; wherein each two adjacent ones of the first touch electrodes are electrically connected through the metal line; and the protective layer is disposed on the metal line.

The display panel further comprises a plurality of bridges disposed at one side of the touch electrodes away from the light shielding layer, wherein the bridges are disposed corresponding to the intersections of the first touch electrodes and the second touch electrodes, and each two adjacent ones of the second touch electrodes in each row are electrically connected through the bridge.

The display panel further comprises an insulating layer disposed between the metal lines and the bridges, wherein a plurality of through holes are defined in the insulating layer, and each two adjacent second touch electrodes in each row are electrically connected to a corresponding one of the bridges through the through holes.

The touch structure further comprises a buffer layer, the bridge is disposed on the buffer layer, and the insulating layer is disposed on the buffer layer.

Advantages of the present invention: The present invention has beneficial effects that an electrode gap is defined between touch electrodes, and a light shielding layer is disposed above the electrode gap to avoid an uneven brightness problem of the display panel resulting from the overly large electrode gap, thereby improving display uniformity of the display panel and improving display performance.

### BRIEF DESCRIPTION OF DRAWINGS

In order to more clearly illustrate the embodiments of the present disclosure or related art, figures which will be described in the embodiments are briefly introduced hereinafter. It is obvious that the drawings are merely for the purposes of illustrating some embodiments of the present disclosure, and a person having ordinary skill in this field can obtain other figures according to these figures without an inventive work.

FIG. 1 is a schematic structural view illustrating a conventional touch structure;

FIG. 2 is a schematic structural view illustrating a touch structure according to one embodiment of the present invention;

FIG. 3 is a cross-sectional view illustrating the touch structure according to one embodiment of the present invention; and

FIG. 4 is a schematic structural view illustrating a display panel according to one embodiment of the present invention.

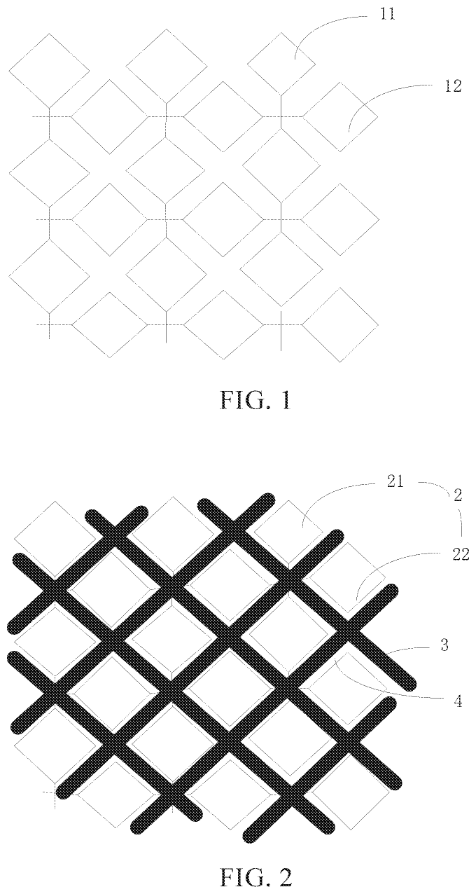

### DETAILED DESCRIPTION OF EMBODIMENTS

Embodiments of the present invention are described below with reference to the accompanying drawings. The following description can fully explain a technical content of the present invention to ease understanding of the present invention. However, the present invention may be embodied in many different forms, so the protection scope of the present invention is not limited to the embodiments set forth herein.

The terminology used in the description of the present invention is for illustrative purposes. Expressions in the singular include the plural unless otherwise specifically indicated. In the present disclosure, it is to be understood that the terms such as “comprising” and “including” indicate inclusion of one or more features, numbers, steps, actions, or combinations thereof but do not preclude the inclusion of one or more other features, numbers, steps, actions, or combinations thereof. The same reference numerals in the drawings denote the same parts/components.

Please refer to FIG. 2 which is a schematic structural view illustrating a touch structure according to one embodiment of the present invention.

Referring to FIG. 2, a touch structure is provided according to one embodiment of the present invention, the touch structure comprising a plurality of touch electrodes 2 and a light shielding layer 3. The touch electrode 2 can be formed by a metal line. Multiple metal lines surround to form multiple grid units, and each grid unit is a touch electrode 2, wherein each grid unit can have a diamond shape. In other words, each touch electrode 2 can be diamond shaped. The touch electrodes 2 are disposed in a same layer to form a touch layer, and an electrode gap 4 is disposed between each adjacent two touch electrodes 2 to prevent the touch electrodes 2 from being short-circuited with each other. The light shielding layer 3 is disposed at one side of the touch layer, wherein the light shielding layer 3 is disposed corresponding to the electrode gaps 4. In other words, an orthographic projection of the light shielding layer 3 projected onto the touch layer is located within the electrode gaps 4.

In practice, the touch electrodes 2 are first formed, a layer of light shielding material is applied at one side of the touch electrodes 2, and then the light shielding material applied is exposed and developed to form a light shielding pattern over the electrode gaps 4. The light shielding pattern constitutes the light shielding layer 3. The light shielding material of the light shielding layer 3 can be a black matrix photoresist material.

According to the present embodiment, the light shielding layer 3 is disposed above the electrode gaps 4. When the touch structure is used in a display panel, the touch structure avoids an uneven brightness problem of the display panel resulting from the overly large electrode gap 4 between the touch electrodes 2 and improves display uniformity of the display panel.

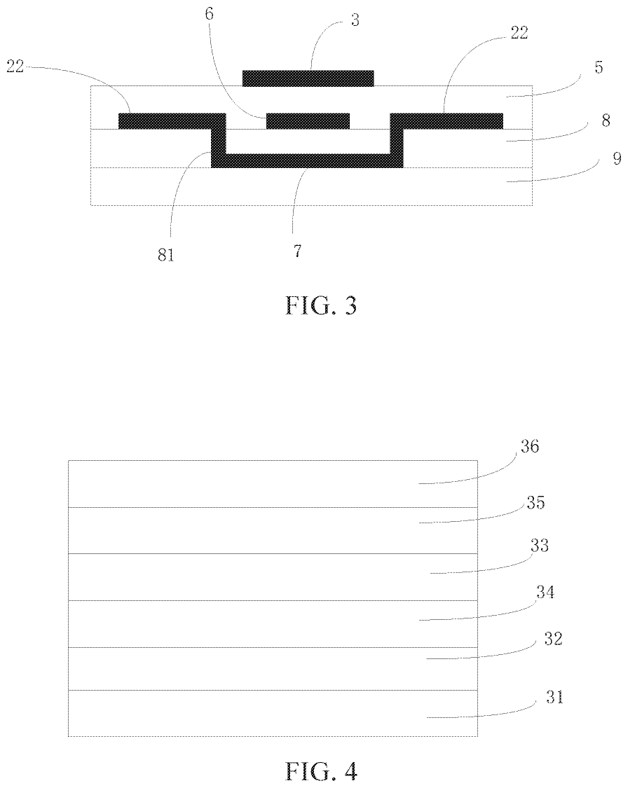

Referring to FIG. 3, the touch structure further comprises a protective layer 5. The protective layer 5 is disposed between the touch layer and the light shielding layer 3. Specifically, the protective layer 5 is disposed on the touch electrodes 2, and the light shielding layer 3 is disposed on the protective layer 5. The protective layer 5 is made of an organic material, and the protective layer 5 is used to protect the touch electrodes 2.

Further, as shown in FIG. 2, the touch electrodes 2 comprise a plurality of first touch electrodes 21 and a plurality of second touch electrodes 22, and the first touch electrodes 21 and the second touch electrodes 22 are electrically insulated from each other and intersect with each other to form a mutual capacitive electrode structure.

It should be noted that the first touch electrodes 21 can be touch sensing electrodes (RX), and the second touch electrodes 22 can be touch driving electrodes (TX). The first touch electrodes 21 and the second touch electrodes 22 are arranged in a crisscross manner, and the first touch electrodes 21 and the second touch electrodes 22 are electrically insulated at their intersections, so that the first touch electrodes 21 and the second touch electrodes 22 are electrically insulated from each other.

In detail, the first touch electrodes 21 are arranged in a plurality of columns along a first direction. Each two adjacent ones of the first touch electrodes 21 in each column are electrically connected to each other. The second touch electrodes 22 are arranged in a plurality of rows along a second direction. Each two adjacent ones of the second touch electrodes 22 in each cow are electrically connected to each other.

It should be noted that, the first touch electrodes 21 are arranged in a plurality of columns along a first direction, and the first touch electrodes 21 of each column are electrically connected to each other. The second touch electrodes are arranged in a plurality of rows along a second direction. The second touch electrodes of each row are electrically connected to each other. The first direction is perpendicular to the second direction. For example, the first direction is a vertical direction, and the second direction is a horizontal direction. In other words, the first touch electrodes 21 of each column extend in the vertical direction, and the second touch electrodes 22 of each row extend in the horizontal direction, so that the first touch electrodes 21 and the second touch electrodes 22 are arranged in a crisscross manner.

As shown in FIG. 3, a metal line 6 is disposed at each intersection of the first touch electrodes 21 and the second touch electrodes 22; wherein each two adjacent ones of the first touch electrodes 21 of each column are electrically connected through the metal line 6.

It should be noted that, the metal line 6 belongs to the touch layer. That is to say, the metal lines 6 is disposed in the same layer as the first touch electrodes 21 and the second touch electrodes 22, and the metal line 6 is disposed between each two adjacent first touch electrodes 21 of each column. Two ends of the metal line 6 are connected to two adjacent first touch electrodes 21, respectively, thereby electrically connecting each two adjacent first touch electrodes 21 of each column. The protective layer 5 is also disposed on the metal line 6 for protecting the metal line 6.

As shown in FIG. 3, a plurality of bridges 7 are disposed at one side of the touch electrodes 2 away from the light shielding layer 3, wherein the bridges 7 are disposed corresponding to the intersections of the first touch electrodes 21 and the second touch electrodes 22, and each two adjacent ones of the second touch electrodes 22 in each row are electrically connected through the bridge 7.

It should be noted that, the bridges 7 and the touch layer are in different layers. That is to say, the bridges 7 are disposed in a different layer from the first touch electrodes 21, the second touch electrode s22, and the metal lines 6. The bridges 7 can be disposed below the touch layer, and each two adjacent second touch electrodes 22 in each row has one bridge 7 between them. Each two adjacent second touch electrodes 22 of each row extend toward their corresponding bridge 7 to be respectively connected to the two ends of the bridge 7 to establish an electrical connection between each two adjacent second touch electrodes 22 of each row.

In the present embodiment, each two adjacent first touch electrodes 21 in each column are electrically connected to each other in the touch layer, and each two adjacent second touch electrodes 22 in each row are disconnected in the touch layer and electrically connected to each other through the bridge 7 in the different layer, thus preventing the first touch electrodes 21 and the second touch electrodes 22 from being short-circuited, thereby effectively ensuring electrical insulation between the first touch electrodes 21 and the second touch electrodes 22.

Furthermore, as shown in FIG. 3, an insulating layer 8 is disposed between the metal lines 6 and the bridges 7. A plurality of through holes 81 are defined in the insulating layer 8, and each two adjacent ones of the second touch electrodes 22 in each row are electrically connected to a corresponding one of the bridges 7 through the through holes 81.

It should be noted that the insulating layer 8 is used to insulate the metal lines 6 from the bridges 7. The insulating layer 8 is disposed between the touch layer and the bridges 7. Specifically, the insulating layer 8 is disposed on the bridges 7. The first touch electrodes 21, the second touch electrodes 22, and the metal lines 6 are disposed on the insulating layer 8. The protective layer 5 is disposed on the first touch electrodes 21, the second touch electrodes 22, the metal lines 6, and the insulating layer 8.

Two through holes 81 in the insulating layer 8 are arranged corresponding to each two adjacent second touch electrodes 22 in each row, and the two through holes 81 are disposed corresponding to two ends of the bridge 7. Each two adjacent touch electrodes 22 of each row extend to their corresponding through holes, respectively, and are connected to the corresponding bridge 7 to thereby establish an electrical connection between each two adjacent second touch electrodes 22 in each row.

The touch structure further comprises a buffer layer 9, the bridges 7 are disposed on the buffer layer 9, and the insulating layer 8 is disposed on the buffer layer 9.

In practice, the buffer layer 9 is formed first, the bridges 7 are formed on the buffer layer 9, the insulating layer 8 is formed on the buffer layer 9 and the bridges 7, then the first touch electrodes 21, the second touch electrodes 22, and the metal lines 6 are formed on the insulating layer 8, after that the protective layer 5 is formed on the first touch electrodes 21, the second touch electrodes 22, the metal lines 6, and the insulating layer 8, and finally the light shielding layer 3 is formed on the protective layer 5.

It can be known from the above that, the present invention provides a touch structure having electrode gaps defined between touch electrodes, and a light shielding layer is disposed above the electrode gaps to avoid an uneven brightness problem of the display panel resulting from the overly large electrode gap, thereby improving display uniformity of the display panel and improving display performance.

FIG. 4 is a schematic structural view illustrating a display panel according to one embodiment of the present invention.

Referring to FIG. 4, the display panel comprises a substrate 31, a light emitting layer 32, and a touch structure 33. The flexible substrate 31 can be made of polyimide (PI). The touch structure 33 is the touch structure in the above embodiment, and details thereof are not repeated for brevity. The light emitting layer 32 is disposed on one side of the flexible substrate 31, and the touch structure 33 is disposed at one side of the light emitting layer 32 away from the flexible substrate 31.

The light emitting layer 32 comprises a plurality of sub-pixels arranged in a spaced-apart manner, the spaced-apart sub-pixels are arranged in an array pattern, and a pixel gap is defined between adjacent sub-pixels, and metal lines of the touch electrodes 2 in the touch structure 33 are arranged corresponding to the pixel gaps. The orthographic projection of the touch electrodes 2 projected on the light emitting layer 32 is located in the pixel gaps, so that the sub-pixels can display images normally.

Moreover, as shown in FIG. 4, the display panel further comprises a thin film encapsulation layer 34, a polarizer plate 35, and a flexible cover 36. The thin film encapsulation layer 34 is disposed between the light emitting layer 32 and the touch structure 33. The polarizer plate 35 is disposed on one side of the touch structure 33 away from the flexible substrate 31. The flexible cover 36 is disposed on one side of the polarizer plate 35 away from the flexible substrate 31. The thin film encapsulation layer 34 is used to encapsulate the light emitting layer 32.

It can be known from the above that, the present invention provides a display panel having electrode gaps defined between touch electrodes, and a light shielding layer is disposed above the electrode gaps to avoid an uneven brightness problem of the display panel resulting from the overly large electrode gap, thereby improving display uniformity of the display panel and improving display performance.

Although the present invention has been disclosed above with reference to preferable embodiments, the preferable embodiments are not intended to limit the protection scope of the present invention. Those skilled in the art can make various modifications without departing from the spirit and protection scope of the present invention. The protection scope of the present invention is defined by the appended claims.

What is claimed is:

1. A touch structure, comprising:
a plurality of touch electrodes, an electrode gap defined between each adjacent two of the touch electrodes; and
a light shielding layer disposed at one side of the touch electrodes, wherein the light shielding layer is disposed corresponding to the electrode gaps.

2. The touch structure according to claim 1, wherein the light shielding layer is made of a black matrix photoresist material.

3. The touch structure according to claim 1, wherein the touch structure further comprises a protective layer, the protective layer is disposed on the touch electrodes, and the light shielding layer is disposed on the protective layer.

4. The touch structure according to claim 3, wherein the touch electrodes comprise a plurality of first touch electrodes and a plurality of second touch electrodes, and the first touch electrodes and the second touch electrodes are electrically insulated from each other and intersect with each other to form a mutual capacitive electrode structure.

5. The touch structure according to claim 4, wherein the first touch electrodes are arranged in a plurality of columns along a first direction; each two adjacent ones of the first touch electrodes in each column are electrically connected to each other; the second touch electrodes are arranged in a plurality of rows along a second direction; each two adjacent ones of the second touch electrodes in each cow are electrically connected to each other; and the first direction is perpendicular to the second direction.

6. The touch structure according to claim 5, further comprising a metal line disposed at each intersection of the first touch electrodes and the second touch electrodes; wherein each two adjacent ones of the first touch electrodes of each column are electrically connected through the metal line; and the protective layer is disposed on the metal line.

7. The touch structure according to claim 6, further comprising a plurality of bridges disposed at one side of the touch electrodes away from the light shielding layer, wherein the bridges are disposed corresponding to the intersections of the first touch electrodes and the second touch electrodes, and each two adjacent ones of the second touch electrodes in each row are electrically connected through the bridge.

8. The touch structure according to claim 7, further comprising an insulating layer disposed between the metal lines and the bridges, wherein a plurality of through holes are defined in the insulating layer, and each two adjacent ones of the second touch electrodes in each row are electrically connected to a corresponding one of the bridges through the through holes.

9. The touch structure according to claim 8, further comprising a buffer layer, wherein the bridges are disposed on the buffer layer, and the insulating layer is disposed on the buffer layer.

10. A display panel, comprising:
a substrate;
a light emitting layer disposed on the substrate; and
a touch structure disposed at one side of the light emitting layer away from the substrate, the touch structure comprising:
a plurality of touch electrodes, an electrode gap defined between each two adjacent ones of the touch electrodes; and
a light shielding layer disposed at one side of the touch electrodes away from the light emitting layer, wherein the light shielding layer is disposed corresponding to the electrode gaps.

11. The display panel according to claim 10, wherein the light shielding layer is made of a black matrix photoresist material.

12. The display panel according to claim 10, wherein the touch structure further comprises a protective layer, the protective layer is disposed on the touch electrodes, and the light shielding layer is disposed on the protective layer.

13. The display panel according to claim 12, wherein the touch electrodes comprise a plurality of first touch electrodes and a plurality of second touch electrodes, and the first touch electrodes and the second touch electrodes are insulated from each other and intersect with each other to form a mutual capacitive electrode structure.

14. The display panel according to claim 13, wherein the first touch electrodes are arranged in a plurality of columns along a first direction; each two adjacent ones of the first touch electrodes in each column are electrically connected to each other; the second touch electrodes are arranged in a plurality of rows along a second direction; each two adjacent ones of the second touch electrodes in each cow are electrically connected to each other; and the first direction is perpendicular to the second direction.

15. The display panel according to claim 14, further comprising a metal line disposed at each intersection of the first touch electrodes and the second touch electrodes; wherein each two adjacent ones of the first touch electrodes are electrically connected through the metal line; and the protective layer is disposed on the metal line.

16. The display panel according to claim 15, further comprising a plurality of bridges disposed at one side of the touch electrodes away from the light shielding layer, wherein the bridges are disposed corresponding to the intersections of the first touch electrodes and the second touch electrodes, and each two adjacent ones of the second touch electrodes in each row are electrically connected through the bridge.

17. The display panel according to claim 16, further comprising an insulating layer disposed between the metal lines and the bridges, wherein a plurality of through holes are defined in the insulating layer, and each two adjacent second touch electrodes in each row are electrically connected to a corresponding one of the bridges through the through holes.

18. The display panel according to claim 17, wherein the touch structure further comprises a buffer layer, the bridge is disposed on the buffer layer, and the insulating layer is disposed on the buffer layer.
